(19) United States
(12) Patent Application Publication
(10) Pub. No.: US 2025/0204191 A1
(43) Pub. Date: Jun. 19, 2025

(54) DISPLAY DEVICE

(71) Applicant: LG Display Co., Ltd., Seoul (KR)

(72) Inventors: Hyunsuk KIM, Paju-si (KR); YoungDock CHO, Paju-si (KR); Soo-Won HWANG, Paju-si (KR); Mingeun CHOI, Paju-si (KR); Sora PARK, Paju-si (KR)

(73) Assignee: LG Display Co., Ltd., Seoul (KR)

(21) Appl. No.: 18/791,072

(22) Filed: Jul. 31, 2024

(30) Foreign Application Priority Data
Dec. 14, 2023 (KR) 10-2023-0181642

(51) Int. Cl. H10K 59/38; H10K 102/00

(52) U.S. Cl. CPC H10K 59/38; H10K 2102/351

(57) ABSTRACT

A display device in one example includes a substrate having a flat area and a bending area disposed at one side of the flat area. A first light emission area is disposed in the flat area and a second light emission area is disposed in the bending area. The first light emission area includes a first emission layer and a first color filter layer disposed on the first emission layer, and the second light emission area includes a second emission layer and a second color filter layer disposed on the second emission layer. The second color filter layer includes a third sub-color filter having a maximum transmittance at a third peak wavelength, and a fourth sub-color filter having a maximum transmittance at a fourth peak wavelength shorter than the third peak wavelength. The third and fourth sub-color filters overlap each other.

### CROSS-REFERENCE TO RELATED APPLICATIONS

This application claims priority to Korean Patent Application No. 10-2023-0181642 filed in the Republic of Korea on Dec. 14, 2023, the entire disclosure of which is hereby expressly incorporated by reference into the present application.

### BACKGROUND

### Field

The present disclosure relates to a display device with improved light luminance properties.

### Discussion of the Related Art

As the information society develops, the demand for display devices for displaying images is increasing in various forms. Accordingly, various display devices such as a liquid crystal display (LCD), a plasma display panel (PDP), and an organic light emitting display (OLED) have been used.

Among such display devices, the organic light emitting display device is a self-luminous type, has an excellent viewing angle and contrast ratio compared to a liquid crystal display (LCD), and does not require a separate backlight. As such, it is possible to be lightweight and thin, and power consumption is advantageous. In addition, the organic light emitting display device has the advantage of being able to drive a DC low voltage, a fast response speed, and particularly low manufacturing cost.

The organic light emitting display device has a structure in which an organic light emitting diode including an emission layer is provided between a cathode injecting electrons and an anode injecting holes. The organic light emitting display device is a display device using the principle that when electrons generated at the cathode and holes generated at the anode are injected into the emission layer, the injected electrons and holes combine to generate excitons, and the generated exitons fall from an excited state to a ground state thereby emitting light.

Since the luminance of light emitted at a certain angle can appear lower than the luminance of light emitted from the front of the display device, there can be an issue that the luminance appears differently depending on the viewing angle of the screen. Furthermore, various products using displays having the curvature on the side have recently been released. In the case of a display having such a curvature, there can be a limitation that the luminance of light emitted from the side having the curvature can decrease compared to the luminance of light emitted from the front of the display device.

### SUMMARY OF THE DISCLOSURE

The present disclosure has been made in view of the above limitations and other disadvantages associated with the related art, and it is an object of the present disclosure to provide a display device that can improve the luminance of light emitted from the side and improve the luminance of light emitted in a bending area with curvature by stacking a first color filter that transmits light having a relatively long wavelength and a second color filter that transmits light having a relatively short wavelength to overlap each other.

In accordance with an aspect of the present disclosure, the above and other objects can be accomplished by the provision of a display device comprising a substrate, a light emitting layer disposed on the substrate and emitting a first color, and a color filter layer disposed on the light emitting layer, wherein the color filter layer includes a first color filter having a maximum transmittance at a first peak wavelength and a second color filter having a maximum transmittance at a second peak wavelength shorter than the first peak wavelength, and the first and second color filters overlap each other.

Furthermore, the above and other objects can be accomplished by the provision of a display device comprising a substrate including a flat area and a bending area disposed at one side of the flat area, wherein a first light emission area disposed in the flat area and a second light emission area disposed in the bending area, the first light emission area includes a first emission layer and a first color filter layer disposed on the first emission layer, and the second light emission area includes a second emission layer and a second color filter layer disposed on the second emission layer, and the second color filter layer includes a third sub-color filter having a maximum transmittance at a third peak wavelength, and a fourth sub-color filter having a maximum transmittance at a fourth peak wavelength shorter than the third peak wavelength, where the third and fourth sub-color filters overlap each other.

### BRIEF DESCRIPTION OF THE DRAWINGS

The above and other objects, features and other advantages of the present disclosure will be more clearly understood from the following detailed description taken in conjunction with the accompanying drawings, in which:

FIG. 1 is a plan view of a display device according to an embodiment of the present disclosure.

FIG. 2 is a schematic perspective view of a display device according to an embodiment of the present disclosure.

FIG. 3 is a cross-sectional view of a display device according to an embodiment of the present disclosure.

FIG. 4 is a cross-sectional view of a first light emission area provided in a display device according to an embodiment of the present disclosure. In this case, FIG. 4 corresponds to the cross section I-I′ of FIG. 1.

FIG. 5 is a graph showing luminance according to wavelength of light emitted from any one light emitting layer of a display device according to an embodiment of the present disclosure.

FIG. 6 is a graph showing transmittance according to wavelength of a color filter of a display device according to an embodiment of the present disclosure.

FIG. 7 is a cross-sectional view of a first light emission area and a second light emission area provided in a display device according to another embodiment of the present disclosure. In this case, FIG. 7 corresponds to cross sections I-I′ and II-II′ of FIG. 1.

FIG. 8 is a graph of luminance according to viewing angles of a first light emission area and a second light emission area included in a display device according to another embodiment of the present disclosure.

FIG. 9 is a cross-sectional view of a second light emission area and a third light emission area provided in a display device according to another embodiment of the present disclosure. In this case, FIG. 9 corresponds to cross sections II-II′ and III-III′ of FIG. 1.

FIG. 10 is a graph showing transmittance of a color filter of a display device according to another embodiment of the present disclosure.

### DETAILED DESCRIPTION OF THE EMBODIMENTS

Advantages and features of the present disclosure, and implementation methods thereof will be clarified through the following embodiments, described with reference to the accompanying drawings. The present disclosure can, however, be embodied in different forms and should not be construed as being limited to the embodiments set forth herein. Rather, these embodiments are provided so that this disclosure will be thorough and complete, and will fully convey the scope of the present disclosure to those skilled in the art.

The shapes, sizes, ratios, angles, and numbers disclosed in the drawings for describing embodiments of the present disclosure are merely examples, and thus the present disclosure is not limited to the illustrated details. Like reference numerals refer to like elements throughout. In the following description, when the detailed description of the relevant known function or configuration is determined to unnecessarily obscure the important point of the present disclosure, the detailed description will be omitted.

In the case in which “comprise,” “have,” and “include” described in the present disclosure are used, another part can also be present unless “only” is used. The terms in a singular form can include plural forms unless noted to the contrary.

In construing an element, the element is construed as including an error region although there is no explicit description thereof.

In describing a positional relationship, for example, when the positional order is described as “on,” “above,” “below,” “beneath”, and “next,” the case of no contact therebetween can be included, unless “just” or “direct” is used.

If it is mentioned that a first element is positioned “on” a second element, it does not mean that the first element is essentially positioned above the second element in the figure. The upper part and the lower part of an object concerned can be changed depending on the orientation of the object. Consequently, the case in which a first element is positioned “on” a second element includes the case in which the first element is positioned “below” the second element as well as the case in which the first element is positioned “above” the second element in the figure or in an actual configuration.

In describing a temporal relationship, for example, when the temporal order is described as “after,” “subsequent,” “next,” and “before,” a case which is not continuous can be included, unless “just” or “direct” is used.

It will be understood that, although the terms “first,” “second,” etc. can be used herein to describe various elements, these elements should not be limited by these terms. These terms are only used to distinguish one element from another and may not define order or sequence. For example, a first element could be termed a second element, and, similarly, a second element could be termed a first element.

It should be understood that the term “at least one” includes all combinations related with any one item. For example, “at least one among a first element, a second element and a third element” can include all combinations of two or more elements selected from the first, second and third elements as well as each element of the first, second and third elements.

Features of various embodiments of the present disclosure can be partially or overall coupled to or combined with each other, and can be variously inter-operated with each other and driven technically. The embodiments of the present disclosure can be carried out independently from each other, or can be carried out together in a co-dependent relationship.

In the drawings, the same or similar elements are denoted by the same reference numerals even though they are depicted in different drawings.

In the embodiments of the present disclosure, a source electrode and a drain electrode are distinguished from each other, for convenience of explanation. However, the source electrode and the drain electrode are used interchangeably. Thus, the source electrode can be the drain electrode, and the drain electrode can be the source electrode. Further, the source electrode in any one embodiment of the present disclosure can be the drain electrode in another embodiment of the present disclosure, and the drain electrode in any one embodiment of the present disclosure can be the source electrode in another embodiment of the present disclosure.

In one or more embodiments of the present disclosure, for convenience of explanation, a source region is distinguished from a source electrode, and a drain region is distinguished from a drain electrode. However, embodiments of the present disclosure are not limited to this structure. For example, a source region can be a source electrode, and a drain region can be a drain electrode. Further, a source region can be a drain electrode, and a drain region can be a source electrode.

In addition, all components of each display device according to all embodiments of the present disclosure are operatively coupled and configured.

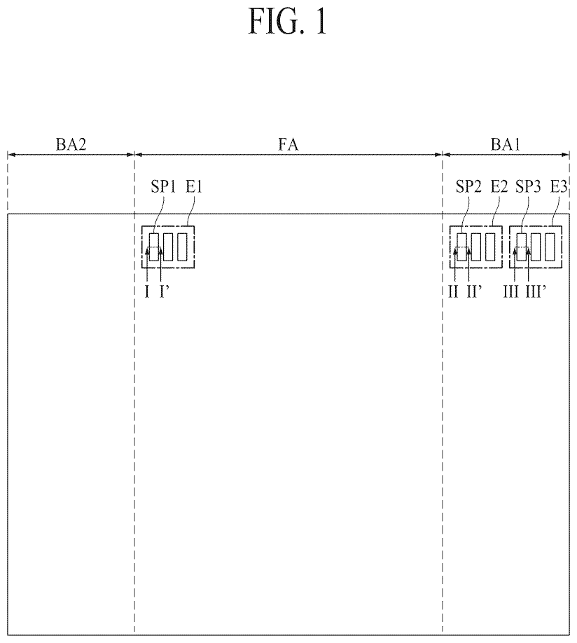

FIG. 1 is a plan view of a display device according to an embodiment of the present disclosure.

As can be seen from FIG. 1, the display device according to an embodiment of the present disclosure can include a flat area FA, a first bending area BA1, and a second bending area BA2.

The flat area FA corresponds to a portion that is provided flat without bending. The flat area FA can include the first light emission area E1. The plurality of first light emission areas E1 are provided, and an image can be displayed while the plurality of first light emission areas E1 emit light.

The first light emission area E1 can include a plurality of first sub-pixels SP1. The plurality of first sub-pixels SP1 provided in the first light emission area E1 can emit red (R) light, green (G) light, and blue (B) light, respectively. Alternatively, the plurality of first sub-pixels SP1 provided in the first light emission area E1 may emit red (R) light, green (G) light, blue (B) light, and white (W) light. Meanwhile, in FIG. 1, a state in which the first light emission area E1 consists of three first sub-pixels SP1 is shown, but the present disclosure is not limited thereto and can include four first sub-pixels SP1. In this case, each of the four first sub-pixels SP1 can emit red (R) light, green (G) light, blue (B) light, and white (W) light. Further, the present disclosure is not limited thereto, and various numbers of first sub-pixels SP1 can emit different colors of light according to technical levels of the art, respectively.

For example, the plurality of sub pixels SP may include red, green, and blue sub-pixels, in which the red, green, and blue sub-pixels may be disposed in a repeated manner. Alternatively, the plurality of sub pixels SP may include red, green, blue, and white sub-pixels, in which the red, green, blue, and white sub-pixels may be disposed in a repeated manner, or the red, green, blue, and white sub-pixels may be disposed in a quad type. For example, the red sub pixel, the blue sub pixel, and the green sub pixel may be sequentially disposed along a row direction, or the red sub pixel, the blue sub pixel, the green sub pixel and the white sub pixel may be sequentially disposed along the row direction. However, in the embodiment of the present disclosure, the color type, disposition type, and disposition order of the sub-pixels are not limiting, and may be configured in various forms according to light-emitting characteristics, device lifespans, and device specifications.

Meanwhile, the sub-pixels may have different light-emitting areas according to light-emitting characteristics. For example, a sub-pixel that emits light of a color different from that of a blue sub-pixel may have a different light-emitting area from that of the blue sub-pixel. For example, the red sub-pixel, the blue sub-pixel, and the green sub-pixel, or the red sub-pixel, the blue sub-pixel, the white sub-pixel, and the green sub-pixel may each has a different light-emitting area.

The first bending area BA1 can be provided at one side of the flat area FA, for example, at a right side. The first bending area BA1 can be a portion where bending (or curving) occurs.

The first bending area BA1 can include a second light emission area E2 provided relatively adjacent to the flat area FA and a third light emission area E3 provided relatively far away from the flat area FA. For example, the second light emission area E2 is closer to the flat area FA with respect to the third light emission area E3. Accordingly, the third light emission area E3 is provided outside the display device according to an embodiment of the present disclosure compared to the second light emission area E2.

The second light emission area E2 can include a plurality of second sub-pixels SP2, and the third light emission area E3 can include a plurality of third sub-pixels SP3. In this case, descriptions of the plurality of second sub-pixels SP2 and the plurality of third sub-pixels SP3 are the same as those of the plurality of first sub-pixels SP1 described above, and thus repeated descriptions thereof will be omitted.

The second bending area BA2 can be provided at another side of the flat area FA, for example, on the left side. The second bending area BA2 can also include a plurality of light emission areas, and each of the plurality of light emission areas can include a plurality of sub-pixels. Since a detailed description related to this is the same as that of the first bending area BA1, a repeated description thereof will be omitted.

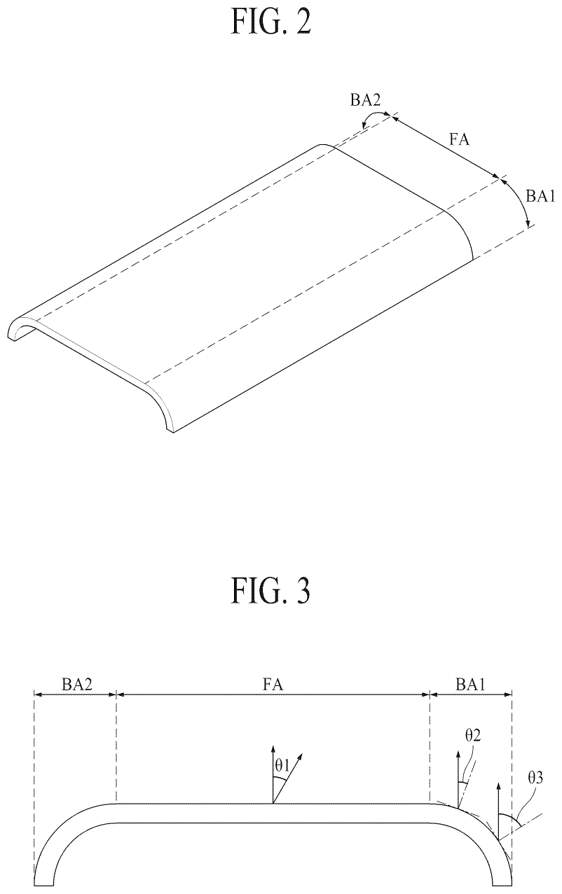

FIG. 2 is a schematic perspective view of a display device according to an embodiment of the present disclosure.

As shown in FIG. 2, the display device according to an embodiment of the present disclosure can include the flat area FA, the first bending area BA1, and the second bending area BA2, as described in the FIG. 1.

The flat area FA can be separately maintained in a flat state without bending or being bent.

The first bending area BA1 can be maintained to be bent at one end of the flat area FA, for example, the right end. Specifically, with respect to the boundary between the flat area FA and the first bending area BA1, one end of the first bending area BA1, for example, the right end can be folded into the back of the display device. Likewise, the second bending area BA2 can be maintained bent at another end of the flat area FA, for example, the left end. Specifically, with respect to the boundary between the flat area FA and the second bending area BA2, one end of the second bending area BA2, for example, the left end can be folded into the back of the display device. Meanwhile, a method in which the first bending area BA1 and the second bending area BA2 are bent is not limited thereto. For example, the first bending area BA1 may be maintained to be bent at an upper end of the flat area FA. Specifically, with respect to the boundary between the flat area FA and the first bending area BA1, the upper end of the first bending area BA1 may be folded into the back of the display device. Likewise, the second bending area BA2 may be maintained bent at a lower end of the flat area FA. Specifically, with respect to the boundary between the flat area FA and the second bending area BA2, the lower end of the second bending area BA2 may be folded into the back of the display device, and not limited thereto.

FIG. 3 is a cross-sectional view of a display device according to an embodiment of the present disclosure.

As shown in FIG. 3, the display device according to an embodiment of the present disclosure can include a flat area FA, a first bending area BA1, and a second bending area BA2. In this case, angles of light emitted in the front direction of the display device in the flat area FA, the first bending area BA1, and the second bending area BA2 can be different. In this case, the front direction can be defined as a direction opposite to a back surface of the display device according to an embodiment of the present disclosure, and the front surface can be defined as an upper surface in the drawing.

Angles of light emitted in the front direction in the flat area FA, the first bending area BA1, and the second bending area BA2 can be different, and angles of light emitted in the front direction from the inside of the first bending area BA1 and the second bending area BA2 and angles of light emitted in the front direction from the outside of the first bending area BA1 and the second bending area BA2 can be different. For example, the inside of the first bending area BA1 and the second bending area BA2 refers to portions close to the flat area FA, and the outside of the first bending area BAL and the second bending area BA2 refers to portions far away from the flat area FA. For example, angles of light emitted in the front direction from portions of the first bending area BA1 and the second bending area BA2 close to the flat area FA and angles of light emitted in the front direction from portions of the first bending area BA1 and the second bending area BA2 far away from the flat area FA may be different. For example, angles of light emitted in the front direction from portions of the first bending area BA1 and the second bending area BA2 close to the flat area FA may be smaller than angles of light emitted in the front direction from portions of the first bending area BA1 and the second bending area BA2 far away from the flat area FA.

Light emitted from the flat area FA in the front direction can be emitted from the upper surface of the display device according to the present disclosure in the normal direction, whereas light emitted from the first bending area BA1 in the front direction can be emitted while forming a predetermined angle from the normal line of the upper surface of the display device. For example, light emitted from a pixel provided inside the first bending area BA1 can be emitted in the front direction while forming a second angle θ2 from a normal line of the upper surface of the display device, and light emitted from a pixel provided outside the first bending area BAL can be emitted in the front direction while forming a third angle θ3 from a normal line of the upper surface of the display device. In this case, as the first bending area BA1 goes gradually outward, an angle formed by the normal line of the upper surface of the display device and the front direction can increase. For example, the second angle θ2 can be formed smaller than the third angle θ3.

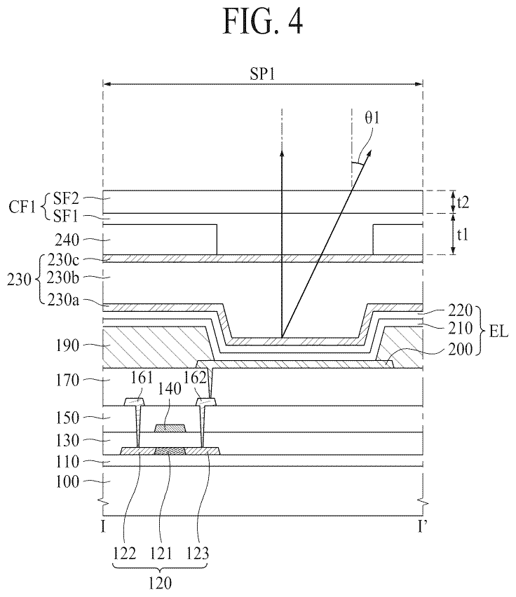

FIG. 4 is a cross-sectional view of a first light emission area provided in a display device according to an embodiment of the present disclosure. In this case, FIG. 4 corresponds to the cross section I-I′ of FIG. 1.

As shown in FIG. 4, a display device according to an embodiment of the present disclosure can include a substrate 100, a buffer layer 110, an active layer 120, a gate insulating layer 130, a gate electrode 140, an interlayer insulating layer 150, a source electrode 161, a drain electrode 162, a planarization layer 170, a bank 190, a first electrode 200, a light emitting layer 210, a second electrode 220, an encapsulation layer 230, a black matrix 240, and a first color filter layer CF1.

The substrate 100 can be formed of glass or plastic. In particular, the substrate 100 can be formed of transparent plastic having flexible characteristics, for example, polyimide. When polyimide is used as the substrate 100, considering that a high-temperature deposition process is performed on the substrate 100, heat-resistant polyimide capable of withstanding high temperatures can be used. The substrate 100 can include a plurality of substrates such as a first substrate and a second substrate. Alternatively, the substrate 100 may be made of any one of polyethylene terephthalate (PET), acrylonitrile-butadiene-styrene copolymer (ABS), polymethyl methacrylate (PMMA), polyethylene naphthalate (PEN), polycarbonate (PC), polyethersulfone (PES), polyarylate (PAR), polysulfone (PSF), cyclic olefin copolymer (COC), triacetylcellulose (TAC), polyvinyl alcohol (PVA), and polystyrene (PS), and the present disclosure is not limited thereto.

The buffer layer 110 is formed on the substrate 100. The buffer layer 110 can block air and moisture to protect the active layer 120. The buffer layer 110 can be made of an inorganic insulating material such as silicon oxide, silicon nitride, or metal oxide, for example, the buffer layer 110 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but is not limited thereto and can be made of an organic insulating material.

The active layer 120 can be formed on the buffer layer 110. The active layer 120 can include any one of a semiconductor material, for example,
an oxide semiconductor, amorphous semiconductor, or polycrystalline semiconductor.

The oxide semiconductor material may have an excellent effect of preventing a leakage current and relatively inexpensive manufacturing cost. The oxide semiconductor may be made of a metal oxide such as zinc (Zn), indium (In), gallium (Ga), tin (Sn), and titanium (Ti) or a combination of a metal such as zinc (Zn), indium (In), gallium (Ga), tin (Sn), or titanium (Ti) and its oxide. Specifically, the oxide semiconductor may include zinc oxide (ZnO), zinc-tin oxide (ZTO), zinc-indium oxide (ZIO), indium oxide (InO), titanium oxide (TiO), indium-gallium-zinc oxide (IGZO), indium-zinc-tin oxide (IZTO), indium zinc oxide (IZO), indium gallium tin oxide (IGTO), and indium gallium oxide (IGO), but is not limited thereto.

The polycrystalline semiconductor material has a fast movement speed of carriers such as electrons and holes and thus has high mobility, and has low energy power consumption and superior reliability. The polycrystalline semiconductor may be made of polycrystalline silicon (poly-Si), but is not limited thereto.

The amorphous semiconductor material may be made of amorphous silicon (a-Si), but is not limited thereto.

The active layer 120 can include a channel part 121, a first connection part 122 provided at one side of the channel part 121, for example, on the left side, and a second connection part 123 provided at another side of the channel part 121, for example, on the right side.

The channel part 121 overlaps the gate electrode 140. By being formed in this way, the channel part 121 is protected by the gate electrode 140 in the conducting process of making a portion of the active layer 120 conductive, and thus semiconductor characteristics can be maintained without being conductive.

The first connection part 122 and the second connection part 123 can have conductive characteristics by a conducting process in which plasma treatment is performed on a semiconductor material using, for example, the gate electrode 140 as a mask. The first connection part 122 and the second connection part 123 by the conducting process have excellent conductive characteristics and can serve as electrodes or wirings.

The gate insulating layer 130 can be formed on the active layer 120. The gate insulating layer 130 can be formed on the entire surface of the substrate 100, but is not limited thereto, and one end and another end of the gate insulating layer 130 can be formed to correspond to one end and another end of the gate electrode 140, respectively by patterning a partial region of the gate insulating layer 130. For example, the gate insulating layer 130 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto. In addition, the gate insulating layer 130 may be formed by atomic layer deposition (ALD) method or metal organic chemical vapor deposition (MOCVD), without being limited thereto.

The gate insulating layer 130 can include a silicon nitride layer SiNx or a silicon oxide layer SiOx, but is not limited thereto. The gate insulating layer 130 can be formed of a single layer or a plurality of layers including an inorganic insulating material and/or an organic insulating material.

The gate electrode 140 can be formed on the gate insulating layer 130.

The gate electrode 140 can include at least one among an aluminum-based metal such as aluminum Al or an aluminum alloy, a silver-based metal such as silver Ag or a silver alloy, a copper-based metal such as copper Cu or a copper alloy, a molybdenum-based metal such as molybdenum Mo or a molybdenum alloy, and chromium Cr, tantalum Ta, neodymium Nd, and titanium Ti. The gate electrode 140 can have a multilayer structure including at least two different conductor films.

The interlayer insulating layer 150 can be formed on the gate electrode 140. The interlayer insulating layer 150 insulates the gate electrode 140 from the source electrode 161 and further insulates the gate electrode 140 from the drain electrode 162. The interlayer insulating layer 150 can be formed of a single layer or a plurality of layers including an inorganic insulating material and/or an organic insulating material. For example, the interlayer insulating layer 150 may be formed by inorganic film in a single layer or in multiple layers, for example, the inorganic film in a single layer may be a silicon oxide (SiOx) film or a silicon nitride (SiNx) film, and inorganic films in multiple layers may formed by alternately stacking one or more silicon oxide (SiOx) films, one or more silicon nitride (SiNx) films, and one or more amorphous silicon (a-Si), but the present disclosure is not limited thereto.

A contact hole can be formed in the interlayer insulating layer 150. Accordingly, a portion of the upper surface of the first connection part 122 of the active layer 120 can be exposed by any one contact hole, and furthermore, a portion of the upper surface of the second connection part 123 of the active layer 120 can be exposed by another contact hole.

The source electrode 161 and the drain electrode 162 can be provided on the interlayer insulating layer 150.

The source electrode 161 can be electrically connected to the first connection part 122 of the active layer 120 by a contact hole, and the drain electrode 162 can be electrically connected to the second connection part 123 of the active layer 120 by a contact hole.

The source electrode 161 and the drain electrode 162 can be formed of the same material as the gate electrode 140, but are not limited thereto, the source electrode 161 and the drain electrode 162 may be formed of different material from the gate electrode 140 and can be formed of a material according to knowledge of the art.

The planarization layer 170 can be formed on the interlayer insulating layer 150, the source electrode 161, and the drain electrode 162. The planarization layer 170 can be formed on the source electrode 161 and the drain electrode 162 to planarize the upper surface of the planarization layer 170. The planarization layer 170 may be configured to protect the thin film transistor including the active layer 120, the gate insulating layer 130, the gate electrode 140, the interlayer insulating layer 150, the source electrode 161 and the drain electrode 162, and to planarize a step caused due to the thin film transistor.

A contact hole can be provided in the planarization layer 170, and a portion of the upper surface of the drain electrode 162 can be exposed by the contact hole. However, in some cases, a portion of the upper surface of the source electrode 161 can be exposed by the contact hole, but not limited thereto.

The planarization layer 170 can be formed of an organic insulating layer material. For example, the planarization layer 170 can be formed of an organic insulating material such as acrylic resin, epoxy resin, phenolic resin, polyamide resin, or polyimide resin.

The organic light emitting element EL includes a first electrode 200, an organic light emitting layer 210, and a second electrode 220. The organic light emitting element EL can emit light of a first color, and the first color can be any one of red (R), green (G), blue (B), and white (W), but is not limited thereto.

The first electrode 200 can be formed on the planarization layer 170, and can be electrically connected to the drain electrode 162 through a contact hole provided in the planarization layer 170. The first electrode 200 can function as an anode.

The bank 190 can be formed on the first electrode 200. In this case, a partial region of the upper surface of the first electrode 200, which is exposed without being covered by the bank 190, becomes a light emitting region.

The bank 190 can be formed of an organic layer such as an acrylic resin, an epoxy resin, a phenolic resin, a polyamide resin, a polyimide resin, or the like.

The bank 190 may be formed of an opaque material to reduce color mixture between the plurality of sub pixels SP and for example, may be formed of black resin, but is not limited thereto.

Although not shown, a spacer may be disposed on the bank 190. The spacer may ensure a gap between a fine metal mask (FMM) and the first electrode 200 so that the FMM is not in contact with the first electrode 200 in a deposition process of a light emitting layer 210.

The light emitting layer 210 can be formed on the first electrode 200. The light emitting layer 210 can include red, green, and blue light emitting layers patterned for each pixel, or can include a white light emitting layer connected to all pixels. When the light emitting layer 210 is formed of a white light emitting layer, the light emitting layer 210 can include, for example, a first stack including a blue light emitting layer, for example, a second stack including a yellow-green light emitting layer, and a charge generation layer provided between the first stack and the second stack, but is not limited thereto. For example, the light-emitting layer 210 may include one or more of a hole injection layer (HIL), a hole transmitting layer (HTL), an electron transmitting layer (ETL) and an electron injection layer (EIL), but the present disclosure is not limited thereto.

The second electrode 220 can be formed on the light emitting layer 210. The second electrode 220 can function as a cathode.

The second electrode 220 can be formed on the entire surface of the bank 190 and the light emitting layer 210, for example.

Depending on bottom emission type or top emission type of the display device, one of the first electrode 200 and the second electrode 220 may include a single layer or multiple layers including an opaque conductive material having a relatively high reflection efficiency, whereas the other of the first electrode 200 and the second electrode 220 may include transparent material, but not limited thereto.

For example, the opaque conductive material may include a material having a relatively low work function such as aluminum (Al), silver (Ag), copper (Cu), lead (Pb), molybdenum (Mo), titanium (Ti) and an alloy thereof, and the present disclosure is not limited thereto.

The encapsulation layer 230 can include a first encapsulation layer 230a, a second encapsulation layer 230b, and a third encapsulation layer 230c. The first encapsulation layer 230a to the third encapsulation layer 230c can be sequentially stacked on the second electrode 220, the first encapsulation layer 230a and the third encapsulation layer 230c can be formed of an inorganic film layer including an inorganic material, and the second encapsulation layer 230b can be formed of an organic film layer including an organic material.

The first encapsulation layer 230a can be formed at the lowermost end of the encapsulation layer 230 to be in contact with the upper surface of the second electrode 220. The first encapsulation layer 230a can be formed of a material such as silicon nitride SiNx, silicon oxide SiOx, silicon oxynitride SiON, or aluminum oxide Al2O3.

The second encapsulation layer 230b can be formed on the first encapsulation layer 230a. The second encapsulation layer 230b can be formed of a material such as acrylic resin, epoxy resin, polyimide, polyethylene PE, or silicon oxycarbon SiOC.

The third encapsulation layer 230c can be formed on the second encapsulation layer 230b. The third encapsulation layer 230c can be formed of the same material as the first encapsulation layer 230a, but not limited thereto, the third encapsulation layer 230c may be formed of different material from the first encapsulation layer 230a.

Meanwhile, the encapsulation layers are not limited to three layers, for example, n layers alternately stacked between inorganic encapsulation layer and organic encapsulation layer (where n is an integer greater than 3) may be included.

The black matrix 240 can be formed on the encapsulation layer 230. Specifically, the black matrix 240 can be formed to overlap the bank 190 to prevent the light emitted from the organic light emitting element EL from being introduced into another adjacent sub-pixel. Accordingly, a limitation or problem in that different lights generated in adjacent sub-pixels are mixed can be prevented or minimized.

The first color filter layer CF1 can be formed on the encapsulation layer 230 and the black matrix 240. The first color filter layer CF1 can pass the light emitted from the organic light emitting element EL provided in the first sub-pixel SP1. Accordingly, the light of the first color emitted by the organic light emitting element EL can pass the light of the first color filter layer CF1. For example, when the light of the first color is green (G), the first color filter layer CF1 can pass the light of green (G), but not limited thereto. For example, when the light of the first color is blue (B), the first color filter layer CF1 may pass the light of blue (B). For example, when the light of the first color is red (R), the first color filter layer CF1 may pass the light of red (R).

According to an embodiment of the present disclosure, the first color filter layer CF1 can include a first sub-color filter SF1 and a second sub-color filter SF2.

The first sub-color filter SF1 and the second sub-color filter SF2 can overlap each other. In this case, the first sub-color filter SF1 can be provided on the encapsulation layer 230, and the second sub-color filter SF2 can be provided on the first sub-color filter SF1. Meanwhile, the present disclosure is not limited thereto, and a second sub-color filter SF2 can be provided on the encapsulation layer 230, and a first sub-color filter SF1 can be provided on the second sub-color filter SF2.

By forming in this way, light emitted from the organic light emitting element EL passes through the first sub-color filter SF1 and the second sub-color filter SF2 and then is directed to the outside.

The first sub-color filter SF1 and the second sub-color filter SF2 can transmit light in different wavelength ranges. For example, the first sub-color filter SF1 can transmit light in a wavelength range of 500 nm to 650 nm, and the second sub-color filter SF2 can transmit light in a wavelength range of 400 nm to 580 nm.

The first sub-color filter SF1 can have a maximum transmittance at a wavelength different from that of the second sub-color filter SF2. Specifically, the first sub-color filter SF1 can have a maximum transmittance at a first wavelength, and the second sub-color filter SF2 can have a maximum transmittance at a second wavelength. In this case, the first wavelength of the first sub-color filter SF1 can be greater than the second wavelength of the second sub-color filter SF2, and a maximum transmittance at the second wavelength of the second sub-color filter SF2 can be greater than a maximum transmittance at the first wavelength of the first sub-color filter SF1, but the present disclosure is not limited thereto.

According to an embodiment of the present disclosure, since the first sub-color filter SF1 and the second sub-color filter SF2 overlap each other and the light emitted from the organic light emitting element EL can pass through the first sub-color filter SF1 and the second sub-color filter SF2 to emit light to the outside, the luminance of the light emitted at the first angle θ1 can be improved.

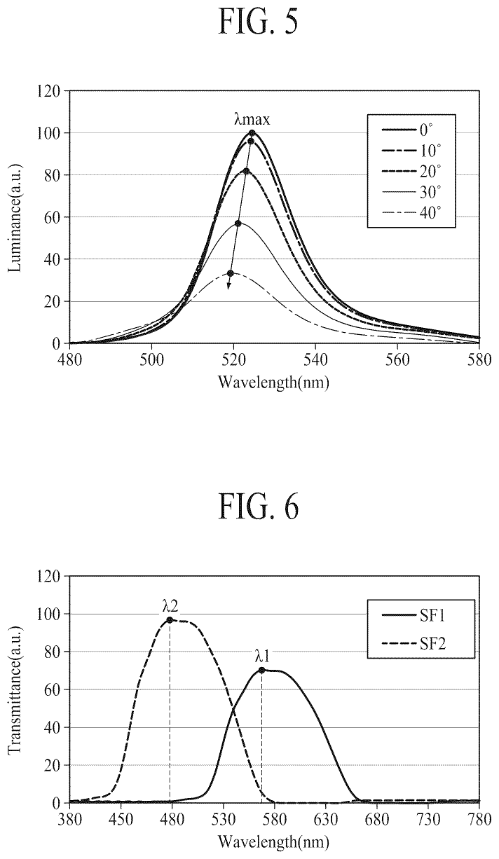

Meanwhile, a principle of increasing the luminance of light passing through the first sub-color filter SF1 and the second sub-color filter SF2 at the first angle θ1 will be described in more detail with reference to FIGS. 5 and 6 below.

FIG. 5 is a graph showing luminance for each wavelength according to a viewing angle of light emitted from the organic light emitting element EL, and FIG. 6 is a graph showing a range of wavelengths transmitted by each of the first sub-color filter SF1 and the second sub-color filter SF2, and light transmittance according to each wavelength range. In this case, the viewing angle can be defined as an angle at which light is emitted from a normal line to an upper surface of the organic light emitting element EL. For example, the viewing angle of light emitted from the front surface can be 0°, and the viewing angle of light emitted at the first angle θ1 can be the first angle θ1.

First, as shown in FIG. 5, when the organic light emitting element (see EL of FIG. 4) provided in the first sub-pixel SP1 emits, for example, green (G), light having a wavelength of approximately 490 to 570 nm can be emitted. In this case, it can be confirmed that the luminance according to the wavelength is relatively lowered as the viewing angle increases. For example, when the viewing angle is 0°, the luminance at the peak wavelength λmax is 100%, whereas when the viewing angle is 40°, the luminance at the peak wavelength λmax is about 32%. In this case, the luminance according to each viewing angle is relatively measured assuming that the luminance measured when the viewing angle is 0°.

Furthermore, as the viewing angle increases, the overall graph of luminance according to the wavelength tends to shift to the left. For example, it can be seen that the graph is relatively skewed to the left when the viewing angle is 40° compared to when the viewing angle is 0°. Therefore, when the viewing angle is 0°, it can be seen that the graph is relatively symmetrical based on the peak wavelength λmax, but when the viewing angle is 40°, the graph is relatively skewed to the left based on the peak wavelength λmax. For example, the peak wavelength λmax tends to shift to the left, when the viewing angle is 40° compared to when the viewing angle is 0°.

In addition, the peak wavelength λmax according to the viewing angle tends to decrease as the viewing angle increases while moving to the left. For example, compared to the case where the viewing angle is 0°, when the viewing angle is 40°, the peak wavelength λmax decreases while moving to the left.

Next, as shown in FIG. 6, the second sub-color filter SF2 can transmit light in a relatively short wavelength band compared to the first sub-color filter SF1. For example, when the organic light emitting element (see EL of FIG. 4) emits green (G), the first sub-color filter SF1 can transmit light in a wavelength range of 500 nm to 650 nm, for example, and the second sub-color filter SF2 can transmit light in a wavelength range of 400 nm to 580 nm.

Furthermore, the first sub-color filter SF1 can have the maximum transmittance at a first wavelength λ1, and the second sub-color filter SF2 can have the maximum transmittance at a second wavelength λ2. In this case, the first wavelength λ1 can be the peak wavelength of light transmitted by the first sub-color filter SF1, and the second wavelength λ2 can be the peak wavelength of light transmitted by the second sub-color filter SF2.

According to an embodiment of the present disclosure, the length of the first wavelength λ1 and the length of the second wavelength λ2 can be within a range of 50 nm from the length of the peak wavelength λmax of the light emitted by the organic light emitting element (see EL of FIG. 4). For example, the length of the first wavelength λ1 is greater than the length of the peak wavelength λmax of the light emitted by the organic light emitting element (see EL of FIG. 4), and the length of the first wavelength λ1 can be within a range of 50 nm from the length of the peak wavelength λmax of the light emitted by the organic light emitting element (see EL of FIG. 4), the length of the second wavelength λ2 is smaller than the length of the peak wavelength λmax of the light emitted by the organic light emitting element (see EL of FIG. 4), and the length of the second wavelength λ2 can be within a range of 50 nm from the length of the peak wavelength λmax of the light emitted by the organic light emitting element (see EL of FIG. 4). On the other hand, FIG. 6 shows the peak wavelength λmax of light emitted by the organic light emitting element (see EL in FIG. 4) provided between the first wavelength λ1 and the second wavelength λ2, but is not limited thereto. For example, the length of the peak wavelength λmax of the light emitted by the organic light emitting element (see EL of FIG. 4) is within a range of 520 nm to 530 nm, the length of the second wavelength λ2 is greater than 470 nm, and the length of the first wavelength λ1 is smaller 580 nm, but the present disclosure is not limited thereto.

According to an embodiment of the present disclosure, the maximum transmittance at a second wavelength λ2 can be higher than the maximum transmittance at a first wavelength λ1. Meanwhile, the luminance of light seen through the actual display device is proportional to the product of the luminance of the light emitted from the organic light emitting element and the transmittance of the color filter layer. Accordingly, since the transmittance of the second sub-color filter SF2 having the maximum transmittance at the second wavelength λ2 is higher than that of the first sub-color filter SF1 having the maximum transmittance at the first wavelength λ1, the luminance of light traveling at the first angle θ1 can be improved. As a result, according to an embodiment of the present disclosure, the luminance of light perceived on the side of the flat area (see FA in FIG. 3) of the display device, for example, light traveling at the first angle θ1, can be improved.

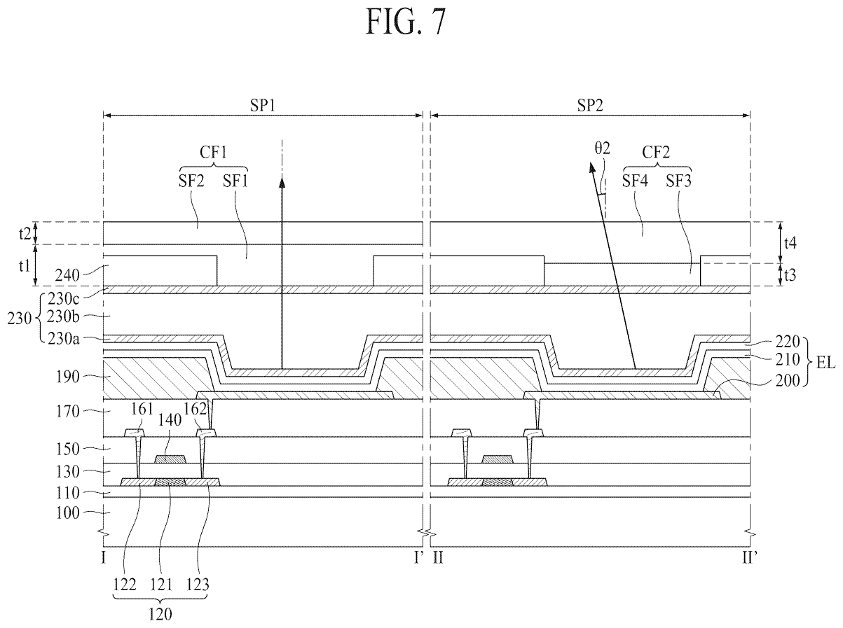

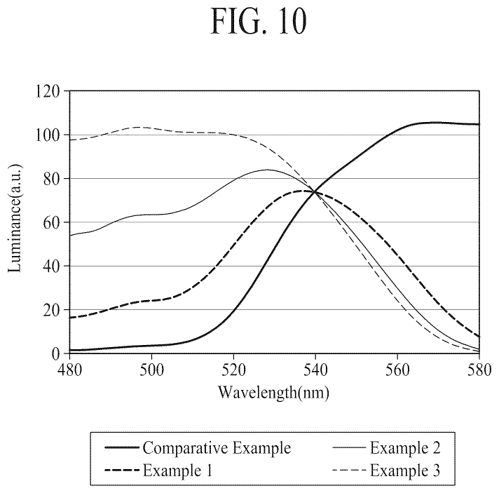

Referring back to FIG. 4, the first sub-color filter SF1 can have a first thickness t1, and the second sub-color filter SF2 can have a second thickness t2. In this case, the first thickness t1 can be the shortest distance between the lower surface and the upper surface of the first sub-color filter SF1, and the second thickness t2 can be the shortest distance between the lower surface and the upper surface of the second sub-color filter SF2. According to an embodiment of the present disclosure, the ratio of the first thickness t1 of the first sub-color filter SF1 to the second thickness t2 of the second sub-color filter SF2 can be adjusted so that luminance of light emitted at the first angle θ1 is improved. Meanwhile, this will be described in more detail with reference to FIGS. 7 and 10.

FIG. 7 is a cross-sectional view of a first light emission area and a second light emission area provided in a display device according to another embodiment of the present disclosure. In this case, FIG. 7 corresponds to cross sections I-I′ and II-II′ of FIG. 1. Meanwhile, in the embodiment of FIG. 7, the first sub-pixel is the same as the first sub-pixel of FIG. 4, and the second sub-pixel is the same as the first sub-pixel of FIG. 4 except for configurations of the third sub-color filter and the fourth sub-color filter, and thus different configurations will be mainly described below.

As shown in FIG. 7, the display device according to the embodiment of the present disclosure can include a substrate 100, a buffer layer 110, an active layer 120, a gate insulating layer 130, a gate electrode 140, an interlayer insulating layer 150, an interlayer insulating layer 150, a source electrode 161, a drain electrode 162, a planarization layer 170, a bank 190, a first electrode 200, a light emitting layer 210, a second electrode 220, an encapsulation layer 230, a black matrix 240, a first color filter layer CF1 provided in the first sub-pixel SP1, and a second color filter layer CF2 provided in the second sub-pixel SP2.

According to an embodiment of the present disclosure, the second sub-pixel SP2 corresponds to any one of the sub-pixels provided in the first bending area (see BA1 of FIG. 3), as described in FIG. 3. The second sub-pixel SP2 is provided in the first bending area (see BA1 of FIG. 3) having a curvature. Accordingly, light emitted from the organic light emitting element EL provided in the second sub-pixel SP2 toward the front surface of the display device according to an embodiment of the present disclosure is emitted while forming a second angle θ2 with a normal line of the upper surface of the organic light emitting element EL.

Unlike the first sub-pixel SP1, the second sub-pixel SP2 can include a second color filter layer CF2.

The second color filter layer CF2 can be formed on the encapsulation layer 230 and the black matrix 240. The second color filter layer CF2 can pass the light emitted from the organic light emitting element EL provided in the second sub-pixel SP2. Accordingly, the light of the first color emitted by the organic light emitting element EL can pass the light of the second color filter layer CF2. For example, when the light of the first color is green (G), the second color filter layer CF2 can pass the light of green (G), but not limited thereto. For example, when the light of the first color is blue (B), the second color filter layer CF2 may pass the light of blue (B). For example, when the light of the first color is red (R), the second color filter layer CF2 may pass the light of red (R).

According to an embodiment of the present disclosure, the second color filter layer CF2 can include a third sub-color filter SF3 and a fourth sub-color filter SF4.

The third sub-color filter SF3 and the fourth sub-color filter SF4 can overlap each other. In this case, the third sub-color filter SF3 can be provided on the encapsulation layer 230, and the fourth sub-color filter SF4 can be provided on the third sub-color filter SF3. Meanwhile, the present disclosure is not limited thereto, and a fourth sub-color filter SF4 can be provided on the encapsulation layer 230, and a third sub-color filter SF3 can be provided on the fourth sub-color filter SF4.

Meanwhile, when a second sub-color filter SF2 is formed on the first sub-color filter SF1 in the first sub-pixel SP1, and a fourth sub-color filter SF4 is formed on the third sub-color filter SF3 in the second sub-pixel SP2, a third sub-color filter SF3 can be formed in the process of forming the first sub-color filter SF1, and a fourth sub-color filter SF4 can be formed in the process of forming the second sub-color filter SF2, and thus the manufacturing time and cost can be shortened. However, the present disclosure is not limited thereto, and when a first sub-color filter SF1 is formed on the second sub-color filter SF2 in the first sub-pixel SP1, and a third sub-color filter SF3 is formed on the fourth sub-color filter SF4 in the second sub-pixel SP2, the manufacturing time and cost can also be shortened.

Light emitted from the organic light emitting element EL is directed to the outside after passing through the third sub-color filter SF3 and the fourth sub-color filter SF4.

The third sub-color filter SF3 and the fourth sub-color filter SF4 can transmit light having different wavelength ranges. For example, the third sub-color filter SF3 can transmit light having a wavelength range of 500 nm to 650 nm, and the fourth sub-color filter SF4 can transmit light having a wavelength range of 400 nm to 580 nm. Meanwhile, the third sub-color filter SF3 is the same as the first sub-color filter SF1 except for the thickness, and the fourth sub-color filter SF4 is the same as the second sub-color filter SF2 except for the thickness, and thus repeated descriptions thereof will be omitted.

The third sub-color filter SF3 can have the maximum transmittance at a wavelength different from that of the fourth sub-color filter SF4. Specifically, the third sub-color filter SF3 can have the maximum transmittance at the third wavelength, and the fourth sub-color filter SF4 can have the maximum transmittance at the fourth wavelength. In this case, the third wavelength of the third sub-color filter SF3 can be greater than the fourth wavelength of the fourth sub-color filter SF4, and the maximum transmittance at the fourth wavelength of the fourth sub-color filter SF4 can be greater than the maximum transmittance at the third wavelength of the third sub-color filter SF3.

According to an embodiment of the present disclosure, since the third sub-color filter SF3 and the fourth sub-color filter SF4 overlap each other and the light emitted from the organic light emitting element EL passes through the third sub-color filter SF3 and the fourth sub-color filter SF4 to emit light to the outside, the luminance of light viewed from the viewing angle of the second angle θ2 can be improved.

The third sub-color filter SF3 can have the third thickness t3, and the fourth sub-color filter SF4 can have the fourth thickness t4. In this case, the third thickness t3 can be the shortest distance between the lower surface and the upper surface of the third sub-color filter SF3, and the fourth thickness t4 can be the shortest distance between the lower surface and the upper surface of the fourth sub-color filter SF4. According to an embodiment of the present disclosure, the luminance of light emitted at the second angle θ2 can be optimized to be improved by adjusting the ratio of the third thickness t3 of the third sub-color filter SF3 to the fourth thickness t4 of the fourth sub-color filter SF4.

According to an embodiment of the present disclosure, the first color filter layer CF1 provided in the first sub-pixel SP1 and the second color filter layer CF2 provided in the second sub-pixel SP2 can be stacked at different thickness ratios. Specifically, a ratio of a thickness of the first sub-color filter SF1 to a thickness of the second sub-color filter SF2 provided in the first color filter layer CF1 and a ratio of a thickness of the third sub-color filter SF3 to a thickness of the fourth sub-color filter SF4 provided in the second color filter layer CF2 can be different from each other.

According to an embodiment of the present disclosure, a ratio of the thickness of the second sub-color filter SF2 to the thickness of the first sub-color filter SF1 can be provided to be smaller than a ratio of the thickness of the fourth sub-color filter SF4 to the thickness of the third sub-color filter SF3. As a result, a ratio of the fourth sub-color filter SF4 allowing light with a relatively short wavelength to pass through in the second sub-pixel SP2 can be higher than a ratio of the second sub-color filter SF2 allowing light with a relatively short wavelength to pass through in the first sub-pixel SP1.

By forming in this way, the light emitted from the organic light emitting element EL of the second sub-pixel SP2 can better pass the light having a relatively short wavelength, thereby improving the luminance of the light emitted at the second angle θ2.

Meanwhile, FIG. 7 illustrates a state in which the first sub-pixel SP1 includes a first sub-color filter SF1 and a second sub-color filter SF2, and the second sub-pixel SP2 includes a third sub-color filter SF3 and a fourth sub-color filter SF4, but the present disclosure is not limited thereto. The first sub-pixel SP1 can include only one layer of the first sub-color filter SF1, and only the second sub-pixel SP2 can include the third sub-color filter SF3 and the fourth sub-color filter SF4. Alternatively, the first sub-pixel SP1 may include the first sub-color filter SF1 and the second sub-color filter SF2, and the second sub-pixel SP2 may include only one layer of the third sub-color filter SF3. Even in the case formed as described above, luminance of light directed to the front of the display device in the first bending area (see BA1 in FIG. 3) or the second bending area (see BA2 in FIG. 3) can be improved.

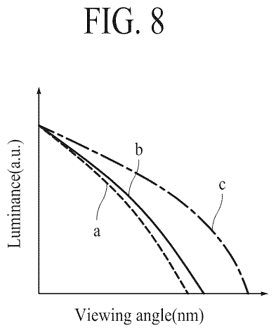

FIG. 8 is a graph of luminance according to viewing angles of a first light emission area and a second light emission area included in a display device according to another embodiment of the present disclosure. In this graph, “a” relates to any one pixel of a display device according to a comparative example, “b” relates to the first sub-pixel SP1 according to an embodiment of FIG. 7, and “c” relates to the second sub-pixel SP2 according to an embodiment of FIG. 7. Meanwhile, any one pixel provided in a display device according to a comparative example does not include a sub-color filter that transmits light having a relatively short wavelength.

As can be seen from a, b, and c, b and c transmit light in a relatively short wavelength band compared to the comparative example, which does not transmit light in a relatively short wavelength band, so it can be seen that the luminance of b and c according to the viewing angle is relatively higher than a.

Furthermore, as can be seen from b and c, the ratio of the thickness of the fourth sub-color filter SF4 to the thickness of the third sub-color filter SF3 is formed to be greater than the ratio of the thickness of the second sub-color filter SF2 to the thickness of the first sub-color filter SF1, so that light in a relatively short wavelength band can be further transmitted in the case of c to secure a relatively higher luminance than b even at a larger viewing angle.

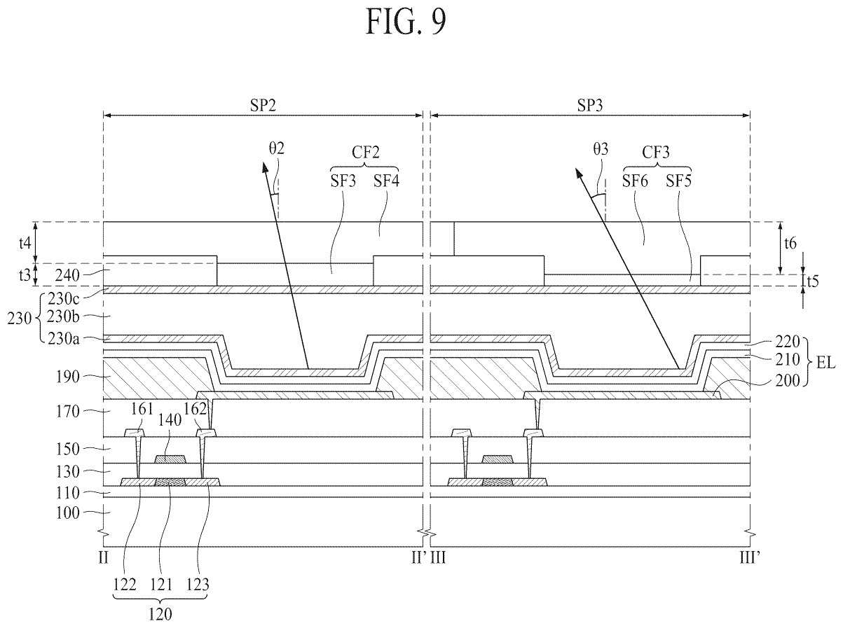

FIG. 9 is a cross-sectional view of a second light emission area and a third light emission area provided in a display device according to another embodiment of the present disclosure. In this case, FIG. 9 corresponds to cross sections II-II′ and III-III′ of FIG. 1. Meanwhile, in an embodiment of FIG. 9, the second sub-pixel is the same as the second sub-pixel of FIG. 7, and the third sub-pixel is the same as the second sub-pixel of FIG. 7 except for configurations of the fifth sub-color filter and the sixth sub-color filter, and thus different configurations will be mainly described below.

As shown in FIG. 9, a display device according to an embodiment of the present disclosure can include a substrate 100, a buffer layer 110, an active layer 120, a gate insulating layer 130, a gate electrode 140, an interlayer insulating layer 150, a source electrode 161, a drain electrode 162, a planarization layer 170, a bank 190, a first electrode 200, a light emitting layer 210, a second electrode 220, an encapsulation layer 230, a black matrix 240, a second color filter layer CF2 provided in the second sub-pixel SP2, and a third color filter layer CF3 provided in the third sub-pixel SP3.

According to an embodiment of the present disclosure, the third sub-pixel SP3 corresponds to any one of the sub-pixels provided in the first bending area (see BA1 of FIG. 3) as described in FIG. 3. The third sub-pixel SP3 is provided outside the display device more than the second sub-pixel SP2 in the first bending area (see BA1 of FIG. 3). For example, the third sub-pixel SP3 is farther away from the flat area of the display device with respect to the second sub-pixel SP2. Accordingly, light emitted from the organic light emitting element EL provided in the third sub-pixel SP3 toward the front surface of the display device according to an embodiment of the present disclosure is emitted while forming a third angle θ3 with a normal line of the upper surface of the organic light emitting element EL. In this case, the third angle θ3 is greater than the second angle θ2 formed by the light directed from the second sub-pixel SP2 toward the front surface of the display device.

Unlike the second sub-pixel SP2, the third sub-pixel SP3 can include a third color filter layer CF3.

The third color filter layer CF3 can be formed on the encapsulation layer 230 and the black matrix 240. The third color filter layer CF3 can pass the light emitted from the organic light emitting element EL provided in the third sub-pixel SP3. Accordingly, the light of the first color emitted by the organic light emitting element EL can pass the third color filter layer CF3. For example, when the light of the first color is green (G), the third color filter layer CF3 can pass the light of green (G), but not limited thereto. For example, when the light of the first color is blue (B), the third color filter layer CF3 may pass the light of blue (B). For example, when the light of the first color is red (R), the third color filter layer CF3 may pass the light of red (R).

According to an embodiment of the present disclosure, the third color filter layer CF3 can include a fifth sub-color filter SF5 and a sixth sub-color filter SF6.

The fifth sub-color filter SF5 and the sixth sub-color filter SF6 can overlap each other. In this case, the fifth sub-color filter SF5 can be provided on the encapsulation layer 230, and the sixth sub-color filter SF6 can be provided on the fifth sub-color filter SF5. Meanwhile, the present disclosure is not limited thereto, and a sixth sub-color filter SF6 can be provided on the encapsulation layer 230, and a fifth sub-color filter SF5 can be provided on the sixth sub-color filter SF6.

By forming in this way, light emitted from the organic light emitting element EL can pass through the fifth sub-color filter SF5 and the sixth sub-color filter SF6 and then be directed to the outside.

The fifth sub-color filter SF5 and the sixth sub-color filter SF6 can transmit light in different wavelength ranges. For example, the fifth sub-color filter SF5 can transmit light in a wavelength range of 500 nm to 650 nm, and the sixth sub-color filter SF6 can transmit light in a wavelength range of 400 nm to 580 nm. Meanwhile, the fifth sub-color filter SF5 is the same as the third sub-color filter SF3 except for the thickness, and the sixth sub-color filter SF6 is the same as the fourth sub-color filter SF4 except for the thickness, and thus repeated descriptions thereof will be omitted.

The fifth sub-color filter SF5 can have the maximum transmittance at a wavelength different from that of the sixth sub-color filter SF6. Specifically, the fifth sub-color filter SF5 can have the maximum transmittance at the fifth wavelength, and the sixth sub-color filter SF6 can have the maximum transmittance at the sixth wavelength. In this case, the fifth wavelength of the fifth sub-color filter SF5 can be greater than the sixth wavelength of the sixth sub-color filter SF6, and the maximum transmittance at the sixth wavelength of the sixth sub-color filter SF6 can be greater than the maximum transmittance at the fifth wavelength of the fifth sub-color filter SF5.

According to an embodiment of the present disclosure, since the fifth sub-color filter SF5 and the sixth sub-color filter SF6 overlap each other and the light emitted from the organic light emitting element EL passes through the fifth sub-color filter SF5 and the sixth sub-color filter SF6 to emit light to the outside, the luminance of light viewed from the viewing angle of the third angle θ3 can be improved.

The fifth sub-color filter SF5 can have a fifth thickness t5, and the sixth sub-color filter SF6 can have a sixth thickness t6. In this case, the fifth thickness t5 can be the shortest distance between the lower surface and the upper surface of the fifth sub-color filter SF5, and the sixth thickness t6 can be the shortest distance between the lower surface and the upper surface of the sixth sub-color filter SF6. According to an embodiment of the present disclosure, the luminance of light emitted at the third angle θ3 can be optimized to be improved by adjusting the ratio of the fifth thickness t5 of the fifth sub-color filter SF5 to the sixth thickness t6 of the sixth sub-color filter SF6.

According to an embodiment of the present disclosure, the second color filter layer CF2 provided in the second sub-pixel SP2 and the third color filter layer CF3 provided in the third sub-pixel SP3 can be stacked at different thickness ratios. Specifically, a ratio of a thickness of the third sub-color filter SF3 to a thickness of the fourth sub-color filter SF4 provided in the second color filter layer CF2 and a ratio of a thickness of the fifth sub-color filter SF5 to a thickness of the sixth sub-color filter SF6 provided in the third color filter layer CF3 can be different from each other.

According to an embodiment of the present disclosure, the ratio of the thickness of the fourth sub-color filter SF4 to the thickness of the third sub-color filter SF3 can be smaller than the ratio of the thickness of the sixth sub-color filter SF6 to the thickness of the fifth sub-color filter SF5. As a result, the ratio of the sixth sub-color filter SF6 allowing light with a relatively short wavelength to pass through in the third sub-pixel SP3 can be higher than the ratio of the fourth sub-color filter SF4 allowing light with a relatively short wavelength to pass through the second sub-pixel SP2.

By forming in this way, the light emitted from the organic light emitting element EL of the third sub-pixel SP3 can better pass the light having a relatively short wavelength, thereby improving the luminance of the light emitted at the third angle θ3.

Meanwhile, although the first sub-pixel SP1 provided in the flat area FA is not specifically shown in FIG. 9, in another example, the first sub-pixel SP1 provided in the flat area FA can include a first sub-color filter SF1 and a second sub-color filter SF2 as shown in FIG. 4. Furthermore, in another example, the first sub-pixel SP1 can include only one layer of the first sub-color filter SF1.

FIG. 10 is a graph showing transmittance of a color filter of a display device according to another embodiment of the present disclosure.

Table 1 below relates to measuring the luminance of light emitted at 40° by adjusting the ratio of thicknesses of the first sub-color filter SF1 and the second sub-color filter SF2 of Comparative Example (also referred to herein as the comparative example) and Examples 1 to 3. In this case, the comparative example includes only the first sub-color filter SF1 that transmits light in a wavelength range of 500 nm to 650 nm, but Examples 1 to 3 include a first sub-color filter SF1 that transmits light in a wavelength range of 500 nm to 650 nm, and a second sub-color filter SF2 that transmits light in a wavelength range of 400 nm to 580 nm, respectively, and are provided by differently adjusting the thickness ratio of each of the first sub-color filter SF1 and the second sub-color filter SF2.

TABLE 1

| | Ratio of | Luminance |
|---|---|---|
| | Thickness (SF1:SF2) | (@40°, %) |
| Comparative | — | 34% |
| Example | | |
| Example 1 | 1:1 | 36% |
| Example 2 | 3:7 | 38% |
| Example 3 | 1:9 | 40% |

Referring to FIG. 10 and Table 1, first, as can be seen by comparing the comparative example and Examples 1 to 3, when both the first sub-color filter SF1 and the second sub-color filter SF2 are provided, for example, when the ratio of the thickness of the first sub-color filter SF1 to the thickness of the second sub-color filter SF2 is 1:1 to 1:9, in the case of Examples 1 to 3, it can be seen that the luminance is increased compared to the comparative example in which only the first sub-color filter SF1 is provided.

Furthermore, referring to Examples 1 to 3, it can be confirmed that the degree of transmission of light in the wavelength range of 400 to 580 nm relatively increases as the ratio of the thickness of the second sub-color filter SF2 to the thickness of the first sub-color filter SF1 increases. As a result, it can be confirmed that the measured luminance at 40° increases as the ratio of the thickness of the second sub-color filter SF2 to the thickness of the first sub-color filter SF1 increases.

Accordingly, the present disclosure can have the following advantages.

According to an embodiment of the present disclosure, the luminance of light emitted in the side direction of the display device can be improved by providing the first sub-color filter and the second sub-color filter that are formed to overlap each other and pass light having different peak wavelengths.

According to an embodiment of the present disclosure, since the ratio of the thickness of the second sub-color filter to the thickness of the first sub-color filter provided in the flat area and the bending area is differently provided, the luminance of light emitted in the front direction in the bending area can be improved.

According to an embodiment of the present disclosure, the luminance of light emitted in the front direction in the bending area can be improved by gradually increasing the ratio of the thickness of the second sub-color filter to the thickness of the first sub-color filter from the inner direction to the outer direction of the bending area.

It will be apparent to those skilled in the art that various substitutions, modifications, and variations are possible within the scope of the present disclosure without departing from the spirit and scope of the present disclosure. Therefore, the scope of the present disclosure is represented by the following claims, and all changes or modifications derived from the meaning, range and equivalent concept of the claims should be interpreted as being included in the scope of the present disclosure.

What is claimed is:

1. A display device comprising:
a light emitting layer disposed on a substrate and configured to emit a first color; and
a color filter layer disposed on the light emitting layer,
wherein the color filter layer includes a first color filter having a maximum transmittance at a first peak wavelength and a second color filter having a maximum transmittance at a second peak wavelength shorter than the first peak wavelength, and
wherein the first color filter and second color filter overlap each other.

2. The display device according to claim 1,
wherein a transmittance of the second color filter greater than a maximum transmittance of the first color filter.

3. The display device according to claim 1,
wherein the first color filter has a first thickness, and the second color filter has a second thickness, and a ratio of the second thickness to the first thickness is equal to or greater than 1.

4. The display device according to claim 1,
wherein the first color filter has a first thickness, and the second color filter has a second thickness, and a ratio of the first thickness to the second thickness ranges from 1:1 to 1:9.

5. The display device according to claim 1,
wherein the first color filter and the second color filter allow light having the first color to pass therethrough.

6. The display device according to claim 1,
wherein the first peak wavelength of the first color filter is greater than a peak wavelength of the light emitting layer, and a difference between the second peak wave length and the peak wave length is within a range of 50 nm.

7. The display device according to claim 1,
wherein the second peak wavelength of the second color filter is smaller than a peak wavelength of the light emitting layer, and a difference between the first peak wave length and the peak wave length is within a range of 50 nm.

8. The display device according to claim 1,
wherein the light emitting layer emits any one of red, green, and blue color lights.

9. A display device comprising:
a substrate including a flat area and a bending area disposed at one side of the flat area,
wherein a first light emission area disposed in the flat area and a second light emission area disposed in the bending area,
the first light emission area includes a first emission layer and a first color filter layer disposed on the first emission layer, and the second light emission area includes a second emission layer and a second color filter layer disposed on the second emission layer,
the second color filter layer includes a third sub-color filter having a maximum transmittance at a third peak wavelength, and a fourth sub-color filter having a maximum transmittance at a fourth peak wavelength shorter than the third peak wavelength, and
the third sub-color filter and fourth sub-color filter overlap each other.

10. The display device according to claim 9,
wherein the first color filter layer includes one layer, and
the second color filter layer includes two layers of the third sub-color filter and the fourth color filter.

11. The display device according to claim 9,
wherein the first color filter layer includes a first sub-color filter having a maximum transmittance at a first peak wavelength and a second sub-color filter having a maximum transmittance at a second peak wavelength, and
the first sub-color filter and second sub-color filter overlap each other.

12. The display device according to claim 11,
wherein the first sub-color filter is disposed under the second sub-color filter, and
the third sub-color filter is disposed under the fourth sub-color filter.

13. The display device according to claim 11,
wherein the first sub-color filter to the fourth color filter include a first thickness, a second thickness, a third thickness, and a fourth thickness, respectively, and
a ratio of the second thickness of the second sub-color filter to the first thickness of the first sub-color filter is smaller than a ratio of the fourth thickness of the fourth sub-color filter to the third thickness of the third sub-color filter.

14. The display device according to claim 11,
wherein a transmittance of the second sub-color filter is greater than a transmittance of the first sub-color filter, and
a transmittance of the fourth sub-color filter is greater than a transmittance of the third sub-color filter.

15. The display device according to claim 11, further comprising:
a third light emission area disposed in the bending area and disposed outside the second light emission area,
wherein the third light emission area includes a third light emitting layer and a third color filter layer disposed on the third light emitting layer,
the third color filter layer includes a fifth sub-color filter having a maximum transmittance at a fifth peak wavelength, and a sixth sub-color filter having a maximum transmittance at a sixth peak wavelength, and
the fifth sub-color filter and sixth sub-color filter overlap each other.

16. The display device according to claim 15,
wherein the third sub-color filter to the sixth color filter include a third thickness, a fourth thickness, a fifth thickness, and a sixth thickness, respectively, and
a ratio of the fourth thickness of the fourth sub-color filter to the third thickness of the third sub-color filter is smaller than a ratio of the sixth thickness of the sixth sub-color filter to the fifth thickness of the fifth sub-color filter.

17. The display device according to claim 15,
wherein a transmittance of the fourth sub-color filter is greater than a transmittance of the third sub-color filter, and
a transmittance of the sixth sub-color filter is greater than a transmittance of the fifth sub-color filter.

18. The display device according to claim 9,
a third light emission area disposed in the bending area and disposed outside the second light emission area,
wherein the third light emission area includes a third light emitting layer and a third color filter layer disposed on the third light emitting layer,
the third color filter layer includes a fifth sub-color filter having a maximum transmittance at a fifth peak wavelength, and a sixth sub-color filter having a maximum transmittance at a sixth peak wavelength, and
the fifth sub-color filter and sixth sub-color filter overlap each other.

19. The display device according to claim 18,
wherein the third sub-color filter to the sixth color filter include a third thickness, a fourth thickness, a fifth thickness, and a sixth thickness, respectively, and
a ratio of the fourth thickness of the fourth sub-color filter to the third thickness of the third sub-color filter is smaller than a ratio of the sixth thickness of the sixth sub-color filter to the fifth thickness of the fifth sub-color filter.

20. The display device according to claim 18,
wherein a transmittance of the fourth sub-color filter is greater than a transmittance of the third sub-color filter, and
a transmittance of the sixth sub-color filter is greater than a transmittance of the fifth sub-color filter.
